(19) United States
(12) Patent Application Publication
(10) Pub. No.: US 2004/0066628 A1
(43) Pub. Date: Apr. 8, 2004

(54) Rapidly self-heat-conductive heat-dissipating module

(76) Inventor: Jefferson Liu, Taichung (TW)

Correspondence Address: Keith Kline, PRO-TECHTOR INT'L SERVICES, 20775 Norada Ct., Saratoga, CA, 95070, US

(21) Appl. No.: 10/603,392

(22) Filed: Jun. 24, 2003

(30) Foreign Application Priority Data
Jul. 26, 2001 (TW) 090212712

(51) Int. Cl. H05K 7/20

(52) U.S. Cl. 361/704

(57) ABSTRACT

A rapidly self-heat-conductive heat-dissipating module is disclosed including: a plurality of heatsinks which are overlapped, but mechanically separable and discontinuous in contacting interface, at least one heat convection super conductive tubes containing high temperature super conductor composites, at least one heat dissipating fans assembled to an identical lateral side of the heatsinks. In addition to serving to buckle heatsinks together, heat convection super conductive tubes containing high temperature super conductor composites transfer heat to heatsink far away from heat generating source rapidly, whereby efficiency of heat dissipating increases. Mechanical separability between buckled heatsinks and discontinuity in contacting interface between heatsinks avoid heat dissipation of heatsink contacting heat source being impaired by the downward heat flow from heatsink far away from heat source. Heat dissipating fans assembled to an identical lateral side of the heatsinks blow cold air to fins of heatsinks to increase heat-dissipating efficiency. Fins of contacting heatsinks can be arranged alternatively to increase heat-dissipating efficiency. A plurality of heatsink sets can be assembled together to form a composite rapidly self-heat-conductive heat-dissipating module to further enhance heat-dissipating efficiency. All characteristics of the present invention mentioned above make rapidly self-heat-conductive heat-dissipating module of the present invention a highly efficient heat-dissipating device.

### BACKGROUND OF THE INVENTION

1. Field of the Invention

The present invention relates to a rapidly self-heat-conductive heat-dissipating module, and particularly to a heat dissipating module which can transfer heat effectively from the CPU of a computer or a device which dissipating a large amount of heat. The present invention comprises a plurality of heatsinks which are overlapped, but can be mechanically separated and are discontinuous in contacting interface and a plurality of heat convection super conductive tubes containing high temperature super conductor composites.

2. Description of Prior Art

The heat dissipating devices for central processing units (CPUs) of computers or high heat generating devices use heatsink devices with a plurality of metal fins to contact the heat sources, absorb heat and then transfer heat to the fins. Then heat-dissipating fans are used to blow cold air for dispersing heat.

The prior art is effective for heat from a small CPU, while for CPU dissipating a large amount of heat, it can not operate effectively since the metal base of heatsink, which contacts heat source is spaced with the distal ends of the fins. Just by the way that heatsink base contacts the heat source (i.e. CPU), the heat from the base of heatsink can not be transferred to the distal ends of the fins, and the root portions of the fins and the distal ends absorb unequal amount of heat. In other words, the portion near root of the base of heatsink absorbs more heat, and the distal ends of fins absorb much less heat. As a result, the root is the only portion of the base of heatsink used to dissipate heat. Therefore, aforesaid conventional heat dissipating device can not match the requirement of the newly developed CPUs with high operation speed.

### SUMMARY OF THE INVENTION

Accordingly, the primary object of the present invention is to provide a rapidly self-heat-conductive heat-dissipating module, wherein a rapidly self-heat-conductive heat-dissipating module has two heatsinks, lower heatsink and upper heatsink, which are overlapped, with fins facing fins, but can be mechanically separated and are discontinuous in contacting interface. At least one heat convection super conductive tubes containing high temperature super conductor composite are engaged with the two heatsinks. A heat-dissipating fan blows air to the two heatsinks for increasing heat-dissipating efficiency.

Another object of the present invention is to provide a rapidly self-heat-conductive heat-dissipating module, wherein a plurality of rapidly self-heat-conductive heat-dissipating modules having heatsinks which are overlapped, with fins facing fins, but mechanically separable and discontinuous in contacting interface, and a plurality of heat convection super conductive tubes containing high temperature super conductor composite can be assembled together and then heat dissipating fan is used to blow cold air. Therefore, the rapidly self-heat-conductive heat-dissipating module can dissipate rapidly and efficiently.

The heat convection super conductive tubes are made of bendable metal tubes (for example, copper, aluminum, etc.) containing high temperature super conductor composites, such as yttrium barium copper oxide (YBCO) superconductor material, thallium barium calcium copper oxide (TBCCO) superconductor material, mercury barium calcium copper oxide (HBCCO) superconductor material, bismuth strontium calcium copper oxide (BSCCO) superconductor material, or other superconductor material, or other rapid heat conductive material. Two ends of the tube are closed for preventing the superconductor material from draining out of the tube. Therefore, heat convection super conductive tube is formed by aforesaid metal tube containing the superconductor material enclosed therein. The principle used is that when the molecules in the tube are heated, heat energy can be transferred by convection due to the rapid oscillation and large friction. Therefore, the heat can be transferred rapidly, and it is called as a heat convection super conductive tube.

Since the heat transfer time in the heat convection super conductive tube from a hot end to a cold end is very short, the temperature difference between the hot end and the cold end is very small and thus an optimum heat transfer can be acquired. It has been appreciated that the speed of heat transfer is about five times of that of copper. Furthermore, it is quicker than general extruded aluminum heat dissipating heatsinks.

As the temperature of hot end and cold end of heat convection super conductive tube is very close, the temperature of the base of lower heatsink, which engaged with hot end of heat convection super conductive tube is highest in lower heatsink, and temperature of top face (base also) of upper heatsink, which engaged with cold end of heat convection super conductive tube is highest in upper heatsink, therefore, temperature of contacting interface between lower heatsink and upper heatsink will be the lowest. Upwards from the contacting interface, temperature rises continuously till top face of upper heatsink, the direction of heat flow in upper heatsink is downward. If the structure is continuous in contacting intrface between lower heatsink and upper heatsink, the downward heat flow of upper heatsink will impair heat dissipating of lower heatsink, and heat dissipating of CPU will be impaired finally. In the present invention, lower heatsink and upper heatsink are mechanically separated and discontinuous in contacting interface.

The various objects and advantages of the present invention will be more readily understood from the following detailed description when read in conjunction with the appended drawing.

### BRIEF DESCRIPTION OF THE DRAWINGS

FIG. 1 is an exploded perspective view of the rapidly self-heat-conductive heat-dissipating module of the present invention having two heatsinks and a plurality of U-shaped heat convection super conductive tubes.

FIG. 2 is a perspective view showing that the elements of FIG. 1 are assembled and a heat dissipating fan is further installed.

FIG. 3 is an exploded perspective view of the rapidly self-heat-conductive heat-dissipating module of the present invention, wherein fins of two heatsinks are alternatively arranged, with a plurality of U-shaped heat convection super conductive tubes and a heat dissipating fan being used.

FIG. 4 is a perspective view showing that the elements of FIG. 3 are assembled.

FIG. 5 is the exploded perspective view of the present invention, wherein two double U-shaped heat convection super conductive tubes and two heatsinksts are assembled.

FIG. 6 is a perspective view showing that the elements of FIG. 5 are assembled.

FIG. 7 is a perspective view showing that, with each heatsink set being formed by two heatsinks, two heatsink sets are assembled together into one composite rapidly self-heat-conductive heat-dissipating module of the present invention.

### DETAILED DESCRIPTION OF THE PREFERRED EMBODIMENTS

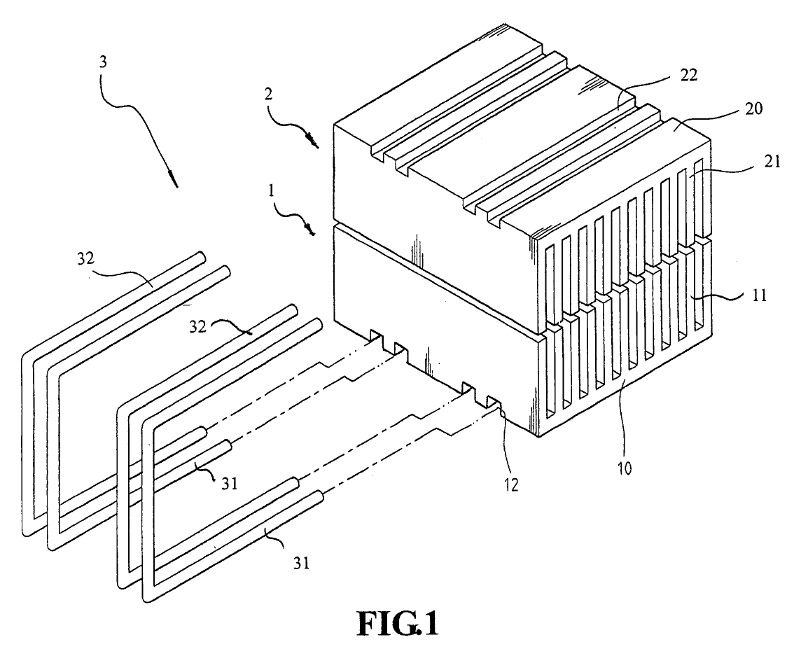

Referring to FIG. 1, the rapidly self-heat-conductive heat-dissipating module of the present invention is illustrated. The heat-dissipating module has heatsink 1, heatsink 2 and a plurality of heat convection super conductive tubes 3.

In the present invention, there are two heatsinks which are mechanically separated and discontinuous in structure.

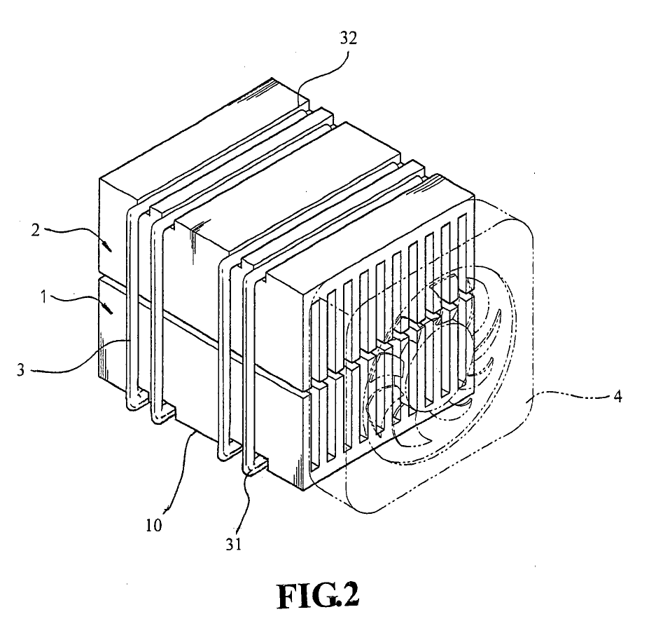

FIG. 1 shows the first embodiment of the present invention. There are heatsink 1 and heatsink 2. Heatsink 1 has a plurality of fins 11 connected on the base 10, heatsink 2 has a plurality of fins 21 connected on the base 20. Base 10 of heatsink 1 has a plurality of trenches 12, base 20 of heatsink 2 (top face of upper heatsink) has a plurality of trenches 22. The heat convection super conductive tubes 3 are bent to have a U shape. Lower sections 31 (hot ends) of the U-shaped tubes 3 are placed in trenches 12, upper sections 32 (cold ends) of U-shaped tubes 3 are placed in another trenches 22. Heatsink 1 and heatsink 2 are assembled as one set. Meanwhile, the heat convection super conductive tubes 3 have the effect of buckling two heatsinks (referring to FIG. 2). The bottom of the base 10 of the heatsink 1 with lower sections 31 (hot ends) of the U-shaped tubes 3 serves for contacting a heat source, such as CPU. Therefore, large amount of heat can be transferred to heatsink 2 through the heat convection super conductive tubes 3.

The reason for using two heatsinks mechanically separated and discontinuous in contacting interface is that no convection between upper heatsink 1 and lower heatsink 2 occurs, since the upper heatsink 1 and lower heatsink 2 are separated, and thus no heat returns.

Since the heat transfer time in the heat convection super conductive tube from a hot end 31 to a cold end 32 is very short, the temperature of difference between the hot end 31 and the cold end 32 is very small. As the temperature of hot end 31 and cold end 32 is very close, the temperature of lower base 10 and upper base 20 will be the highest, and then temperature of contacting face between heatsink 1 and heatsink 2 will be the lowest. Upwards from the contacting face, temperature rises continuously till upper base 20, the direction of heat flow in heatsink 2 is downward. If the structure is continuous between heatsink 1 and heatsink 2, the downward heat flow of heatsink 2 will impair heat dissipating of heatsink 1, and heat dissipating of CPU will be impaired finally. In the present invention, heatsink 1 and heatsink 2 are mechanically separated and discontinuous in contacting interface. Therefore, a rapidly self-heat-conductive heat-dissipating module is formed by the heat convection super conductive tubes 3 containing high temperature super conductor composites, heatsink 1 and heatsink 2, which are mechanically separated and discontinuous in structure.

A heat dissipating fan 4 is assembled at the identical lateral side of the two heatsinks for blowing cold air to the fins 11 and fins 21 to achieve a high efficiency heat dissipation.

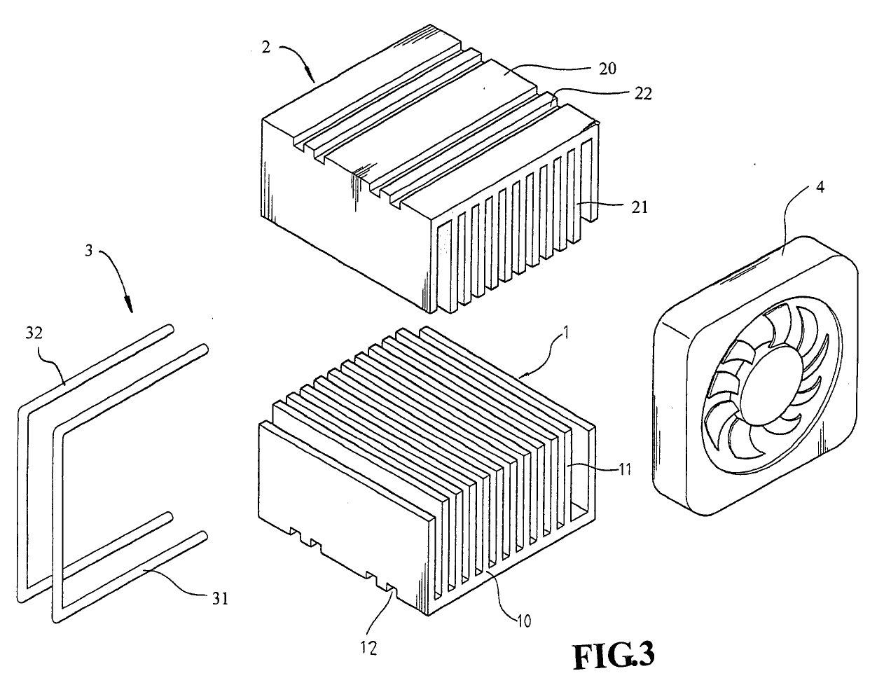

FIG. 3 shows the second embodiment of the present invention is illustrated. There are heatsink 1 and heatsink 2, which are mechanically separated and discontinuous in structure. Base 10 of the heatsink 1 has a plurality of trenches 12, base 20 of the heatsink 2 has a plurality of trenches 22. The heat convection super conductive tubes 3 are bent to have a U shape. Two ends of the U shape tube are placed in trenches 12 and trenches 22.

Heatsink 1 and heatsink 2 are assembled as one set, and the fins of the two heatsinks are alternatively arranged. The alternatively arranged fins can increase the area of heat dissipation.

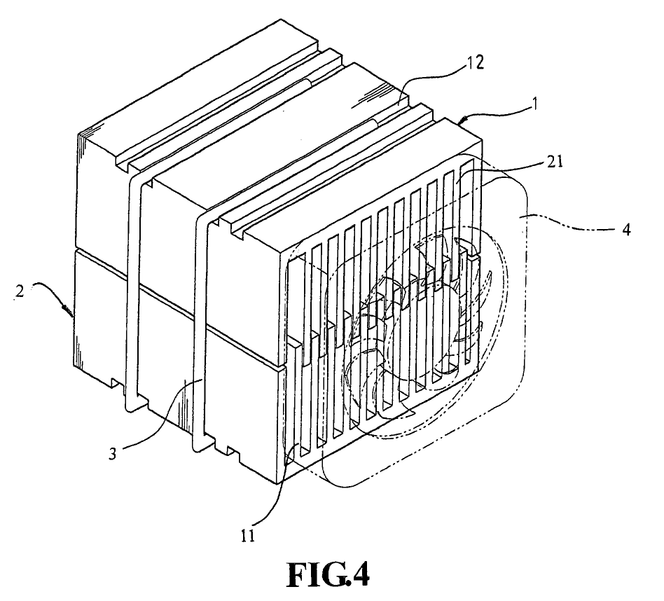

Meanwhile, the heat convection super conductive tube 3 has the effect of buckling two heatsink (referring to FIG. 4). The base 10 of the heatsink 1 with trenches 12 serves for contacting a heat source. Therefore, large amount of heat can be transferred to heatsink 2 through the heat convection super conductive tube 3. Then heat is thus transferred to each heatsink. A heat dissipating fan 4 is assembled at the identical lateral side of the two heatsinks for blowing cold air to the fins 11 and fin 21 to achieve a high efficiency heat dissipation.

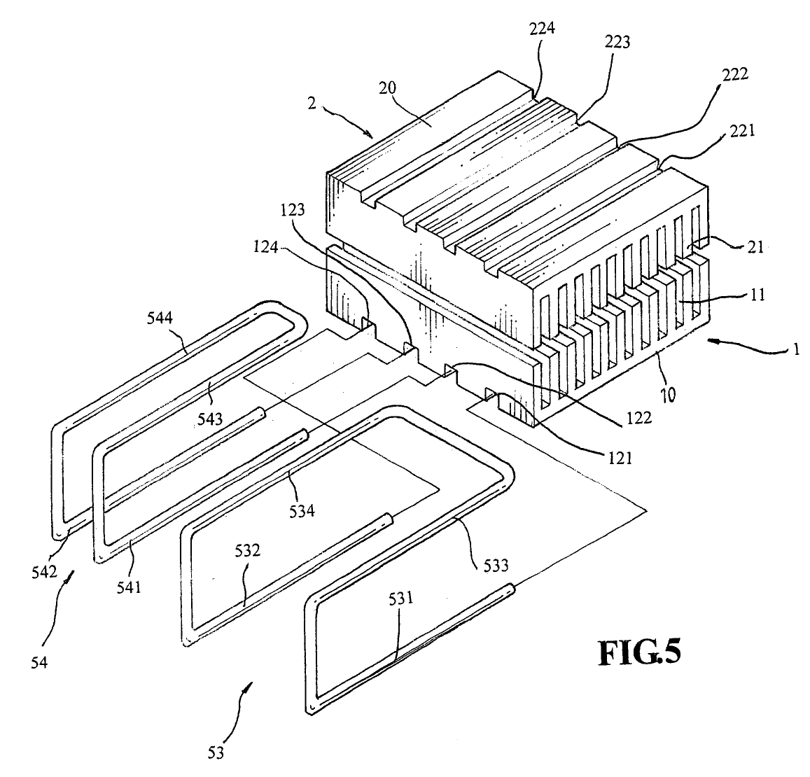

FIG. 5 shows the third embodiment of the present invention. In this the present invention, the heatsinks are identical to those in the first embodiment, which are mechanically separated and discontinuous in structure.

There is difference between heat convection super conductive tubes of FIG. 1 and FIG. 5. There are two heat convection super conductive tube 53 and 54. Both are formed by two U shapes.

One heat convection super conductive tube 53 is wider, and the other 54 is narrower. The two free ends 531, 532 of the double U shapes of the wider heat convection super conductive tube 53 can be placed in the two trenches 12l, 124. The portions of double U shapes of the wider heat convection super conductive tube 53 having no free end 533, 534 are placed in the two trenches 221, 224.

The two free ends 541, 542 of the double U shapes of the narrower heat convection super conductive tube 54 are placed in the two trenches 122, 5123 at the inner sides. The portions of double U shapes of the narrower heat convection super conductive tube 54 having no free end 543, 544 are placed in the two trenches 222, 223 at the inner sides.

Therefore, in addition to transferring through the fins 11, the heat absorbed by the base 10 can be transferred to the heatsink 2 through the heat convection super conductive tubes rapidly.

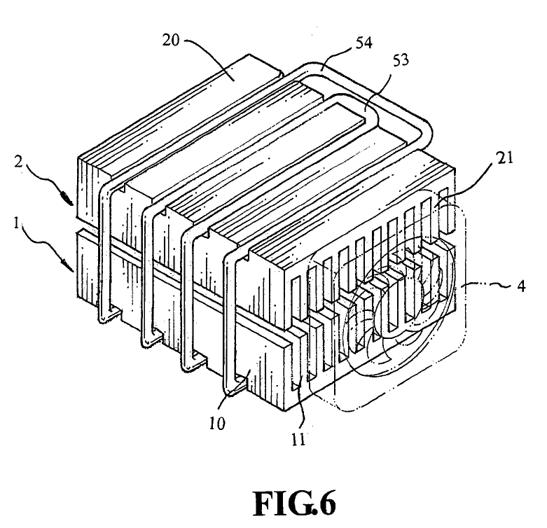

FIG. 6 shows a heat dissipating fan 4 is assembled at the identical lateral side of the two heatsink 1,2 for blowing cold air to the fins 11, 21 to achieve a highly efficient heat dissipation.

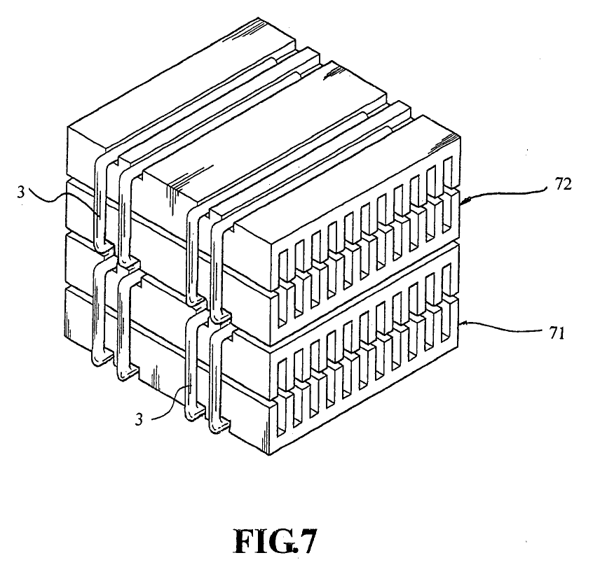

FIG. 7 shows the fourth embodiment of the present invention. In this embodiment, the heatsink sets 71,72 and the heat convection super conductive tube 3 can be assembled together.

The rapidly self-heat-conductive heat-dissipating module of the present invention has the following advantages:

1. Heatsinks of rapidly self-heat-conductive heat-dissipating module of the present invention are mechanically separated and discontinuous in structure, and heat of heatsink contacting heat generating device can dissipate more rapidly.

2. The adoption of heat convection super conductive tube containing high temperature super conductor composites make heat of heat generating device dissipate more rapidly.

3. In the present invention, a plurality of rapidly self-heat-conductive heat-dissipating module can be assembled integrally, the heat from the heat source can dissipate more rapidly.

4. The alternatively arranged fins make dissipating area increase and heat disspate more rapidly.

The present invention are thus described, it will be obvious that modifications and variations may be easily made without departing from the spirit of this invention which is defined by the appended claims. Such modifications and variations are not to be regarded as a departure from the spirit and scope of the present invention, and all such modifications and variations as would be obvious to one skilled in the art are intended to be included within the scope of the following claims.

What is claimed is:

1. A rapidly self-heat-conductive heat-dissipating module, comprising:
a plurality of heatsinks which are overlapped, but can be mechanically separated with each other and are discontinuous in contacting interface, with each said heatsink having a plurality of fins connected on one base, and with a plurality of trenches being installed on the said base;
at least one heat convection super conductive tubes containing high temperature super conductor composite, bent into shapes capable of buckling the heatsink sets of each two of the said heatsinks, with each of the said heat convection super conductive tubes having one portion placed into one of the said trenches of the said base of one said heatsink of the said heatsink set, which near heat source, and the other portion placed into one of the said trenches of the said base of the other said heatsink of the same said heatsink set, which far away from the heat source, whereby heat transferring from the portion near the heat source to the portions far away from the heat source;
at least one heat dissipating fans assembled to an identical lateral side of the said heatsinks.

2. The rapidly self-heat-conductive heat-dissipating module according to claim 1, wherein each of at least one said heat convection super conductive tubes is bent to have a U shape, with one end of each said U shape being placed into one of the said trenches of the said base of one said heatsink of the said heatsink set, the other end of each said U shape being placed into one of the said trenches of the said base of the other said heatsink of the same said heatsink set and the two said heatsinks being buckled into one said heatsink set.

3. The rapidly self-heat-conductive heat-dissipating module according to claim 2, wherein the said fins are alternatively arranged.

4. The rapidly self-heat-conductive heat-dissipating module according to claim 1, wherein the said rapidly self-heat-conductive heat-dissipating module has two said heasinks and two said heat convection super conductive tubes, with each said heat convection super conductive tube being formed by double U shapes, two free ends of the said double U shapes of each said convection super conductive tube being placed into the two said trenches of one said heatsink and the other two portions of the said double U shapes having no said free end being placed into the two said trenches of the other said heatsink, the two heatsinks being buckled into one heatsink set.

5. The rapidly self-heat-conductive heat-dissipating module according to claim 1, further comprising a heat dissipating fan assembled to an identical lateral side of the heatsinks

6. The rapidly self-heat-conductive heat-dissipating module according to claim 1, wherein a plurality of heat dissipating modules formed by heatsinks and heat convection super conductive tubes are assembled together.

7. The rapidly self-heat-conductive heat-dissipating module according to claim 1, wherein a plurality of heat dissipating fans are assembled to an identical lateral side of the said heatsinks
